(19) United States
(12) Patent Application Publication
(10) Pub. No.: US 2025/0133807 A1
(43) Pub. Date: Apr. 24, 2025

(54) SEMICONDUCTOR ELEMENT AND METHOD FOR MANUFACTURING SEMICONDUCTOR ELEMENT

(71) Applicant: TOYODA GOSEI CO., LTD., Kiyosu-shi (JP)

(72) Inventor: Kota YASUNISHI, Kiyosu-shi (JP)

(21) Appl. No.: 18/912,917

(22) Filed: Oct. 11, 2024

(30) Foreign Application Priority Data
Oct. 24, 2023 (JP) 2023-182656

(51) Int. Cl. H01L 29/49; H01L 21/28; H01L 21/3213; H01L 29/423

(52) U.S. Cl. CPC H10D 64/667; H01L 21/28088; H01L 21/32136; H10D 64/513

(57) ABSTRACT

Provided is a semiconductor element in which Al in an electrode on an insulating film is suppressed from diffusing into an insulating film via a surface protective film. The semiconductor element includes a semiconductor layer, an insulating film (gate insulating film) disposed on the semiconductor layer, an electrode (gate electrode) disposed on the insulating film, and a surface protective film covering the semiconductor layer, the insulating film, and the electrode. The electrode includes a first barrier layer preventing Al diffusion into the insulating film, a metal layer formed on the first barrier layer and made of Al or an alloy mainly composed of Al, and a second barrier layer formed on the metal layer and protecting the metal layer. A side surface of the metal layer is disposed inside a side surface of the first barrier layer and inside a side surface of the second barrier layer.

### CROSS-REFERENCE

This application claims priority to Japanese patent application No. 2023-182656 filed on Oct. 24, 2023, the contents of which are fully incorporated herein by reference.

### BACKGROUND OF THE INVENTION

### Technical Field

The present disclosure relates to a semiconductor element and a method for manufacturing the semiconductor element.

### Background Art

As a gate electrode of Metal-Insulator-Semiconductor Field-Effect Transistor (MISFET), a structure is known, in which TIN, Al, and TiN are deposited in this order on a gate insulating film (JP-A-2016-54250). TiN on the gate insulating film side is a layer to prevent Al from diffusing into the gate insulating film, and TiN on Al is a layer to protect Al from oxidation.

### SUMMARY OF THE INVENTION

According to the study of the present inventors, when the gate electrode has a structure of TiN, Al, and TiN deposited and a surface of a semiconductor element is covered with a surface protective film, as in JP-A-2016-54250, there is a risk that the Al in the gate electrode may diffuse into the gate insulating film through the surface protective film during heat treatment in a subsequent step and under operating environment. If Al diffuses into the gate insulating film, it causes unstable operation such as fluctuation of threshold voltage and generation of leakage current.

In view of this background, an object of the present disclosure is to provide a semiconductor element and a method for manufacturing the same, in which Al in an electrode on an insulating film is suppressed from diffusing into an insulating film through a surface protective film.

One aspect of this disclosure is a semiconductor element including:
a semiconductor layer;
an insulating film disposed on the semiconductor layer;
an electrode disposed on the insulating film; and
a surface protective film covering the semiconductor layer, the insulating film, and the electrode,
wherein the electrode includes:
   a first barrier layer to prevent Al from diffusing into the insulating film,
   a metal layer formed on the first barrier layer and made of Al or an alloy mainly composed of Al; and
   a second barrier layer formed on the metal layer to protect the metal layer,
wherein a side surface of the metal layer is disposed inside a side surface of the first barrier layer and inside a side surface of the second barrier layer.

The other aspect of this disclosure is a method for manufacturing a semiconductor element including:
forming an insulating film on a semiconductor layer,
forming an electrode by depositing a first barrier layer to prevent Al from diffusing into the insulating film, a metal layer made of Al or an alloy mainly composed of Al, and a second barrier layer to protect the metal layer in this order on the insulating film,
etching including dry etching the electrode in a direction perpendicular to a main surface of the semiconductor layer to form a predetermined pattern, and dry etching a side surface of the metal layer so that the side surface of the metal layer is disposed inside a side surface of the first barrier layer and inside a side surface of the second barrier layer; and
forming a surface protective film to cover the semiconductor layer and the electrode.

In the above aspects, the side surface of the metal layer is disposed inside the side surface of the first barrier layer and inside the side surface of the second barrier layer. In other words, the side surface of the metal layer is disposed more inward than the side surface of the first barrier layer and more inward than the side surface of the second barrier layer. Therefore, Al in the metal layer is suppressed from diffusing into the insulating film, thereby suppressing unstable operation.

### BRIEF DESCRIPTION OF THE DRAWINGS

FIG. 1 is a cross-sectional view of a semiconductor element according to a first embodiment, in a direction perpendicular to a main surface of a substrate,

FIG. 2 is a schematic view showing steps of manufacturing the semiconductor element according to the first embodiment,

FIG. 3 is a schematic view showing steps of manufacturing the semiconductor element according to the first embodiment,

FIG. 4 is a cross-sectional view of a semiconductor element according to a second embodiment, in a direction perpendicular to a main surface of a substrate,

FIG. 5 is a cross-sectional view of a semiconductor element according to a third embodiment, in a direction perpendicular to a main surface of a substrate,

FIG. 6 is a cross-sectional view of a semiconductor element according to a fourth embodiment, in a direction perpendicular to a main surface of a substrate,

FIG. 7 is a cross-sectional view of a semiconductor element according to a first variation of the fourth embodiment, in a direction perpendicular to a main surface of a substrate,

FIG. 8 is a cross-sectional view of a semiconductor element according to a second variation of the fourth embodiment, in a direction perpendicular to a main surface of a substrate,

FIG. 9 is a cross-sectional view of a semiconductor element according to a fifth embodiment, in a direction perpendicular to a main surface of a substrate,

FIG. 10 shows a variation of the steps of manufacturing the semiconductor element according to the first embodiment.

### DETAILED DESCRIPTION OF PREFERRED EMBODIMENTS

The semiconductor element includes a semiconductor layer, an insulating film disposed on the semiconductor layer, an electrode disposed on the insulating film, and a surface protective film covering the semiconductor layer, the insulating film, and the electrode. The electrode includes a first barrier layer to prevent Al from diffusing into the insulating film, a metal layer formed on the first barrier layer and made of Al or an alloy mainly composed of Al, and a second barrier layer formed on the metal layer to protect the metal layer. Furthermore, a side surface of the metal layer is disposed inside a side surface of the first barrier layer and inside a side surface of the second barrier layer.

In the above semiconductor element, the side surfaces of the metal layer may be covered with an oxide film made of aluminum oxide, thereby further suppressing Al from diffusing into the insulating film.

In the above semiconductor element, a void may be formed between the side surface of the metal layer and the surface protective film, thereby further suppressing Al from diffusing into the insulating film.

In the above semiconductor element, the semiconductor element may have an insulating gate structure, the insulating film may include a gate insulating film, and the electrode may include a gate electrode.

In the above semiconductor element, the semiconductor layer includes a trench, the insulating film may include a gate insulating film continuously disposed over a bottom surface of the trench, a side surface of the trench, and ta vicinity of the trench of a surface of the semiconductor layer, the electrode. The electrode may include a gate electrode continuously disposed over the bottom of the trench, the side surface of the trench, and the vicinity of the trench of the surface of the semiconductor layer through the insulating film.

A method of manufacturing a semiconductor element includes the steps of:
forming an insulating film on a semiconductor layer, forming an electrode by depositing a first barrier layer to prevent Al from diffusing into the insulating film, a metal layer made of Al or an alloy mainly composed of Al, and a second barrier layer to protect the metal layer in this order on the insulating film;
etching including dry etching the electrode in a direction perpendicular to a main surface of the semiconductor layer to form a predetermined pattern, and dry etching a side surface of the metal layer so that the side surface of the metal layer is disposed inside a side surface of the first barrier layer and inside a side surface of the second barrier layer; and
forming a surface protective film to cover the semiconductor layer and the electrode.

The above method for manufacturing the semiconductor element, further comprising the step of forming a trench in the semiconductor layer before the forming the insulating film, wherein the insulating film is formed in a continuous film over a bottom surface of the trench, on a side surface of the trench, and a vicinity of the trench of the surface of the semiconductor layer, and the electrode is formed continuously over the bottom surface of the trench, the side surface of the trench, and the vicinity of the trench of the surface of the semiconductor layer through the insulating film.

In the above method for manufacturing the semiconductor element, the etching step may include a vertical dry etching the electrode in the direction perpendicular to the main surface of the semiconductor layer to form a predetermined pattern, and a horizontal dry etching the side surface of the metal layer at an etching pressure higher than that of the vertical dry etching after the vertical dry etching.

In the above method for manufacturing the semiconductor element, in the etching step, dry etching in the direction perpendicular to the main surface of the semiconductor layer and dry etching the side surface of the metal layer may be simultaneously performed. Since there is no need to vary the etching pressure, manufacturing can be facilitated, and productivity can be improved.

In the above method for manufacturing the semiconductor element, the etching may include: dry etching the second barrier layer in the direction perpendicular to the main surface of the semiconductor layer until the metal layer is exposed to form a predetermined pattern; etching the metal layer of dry etching the metal layer in the direction perpendicular to the main surface of the semiconductor layer until the barrier layer is exposed, and dry etching the side surface of the metal layer, after the dry etching the second barrier layer; and dry etching the first barrier layer in the direction perpendicular to the main surface of the semiconductor layer until the insulating film is exposed after the etching the metal layer. By dry etching each layer of the electrode individually, the accuracy of the dimension and shape of each layer can be improved.

The above method for manufacturing the semiconductor element may include the step of oxidizing the side surface of the metal layer to form an oxide film. By forming the oxide film, the diffusion of Al into the insulating film can be further suppressed.

In the above method for manufacturing the semiconductor element, the surface protective film may be formed so that a void remains between the side surface of the metal layer and the surface protective film. The void can further suppress the diffusion of Al into the insulating film.

### First Embodiment

### 1. Configuration of Semiconductor Element

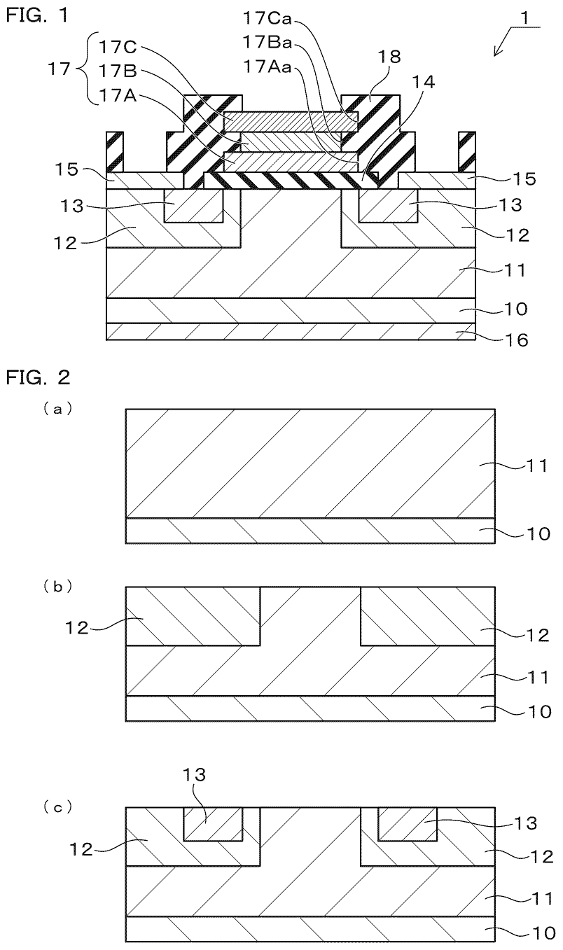

FIG. 1 is a cross-sectional view of a semiconductor element 1 according to a first embodiment, in a direction perpendicular to a main surface of a substrate 10. The direction perpendicular to the main surface of the substrate 10 corresponds to a direction perpendicular to a main surface of a semiconductor layer (11, 12, and 13). As shown in FIG. 1, the semiconductor element 1 according to the first embodiment is a vertical planar type MISFET. The semiconductor element 1 includes a substrate 10, an n-type layer 11, a p-type region 12, an n-type source region 13, a gate insulating film 14, a source electrode 15, a drain electrode 16, a gate electrode 17, and a surface protective film 18. Hereinafter, the n-type layer 11, the p-type region 12, and the n-type source region 13 are referred to as the semiconductor layer.

The substrate 10 is made of Si-doped n⁺-GaN having a c-plane main surface. The substrate 10 has a Si concentration of at least 1×10¹⁸/cm³. The substrate 10 may be made of any material other than GaN, for example, a material capable of growing group III nitride semiconductors and having electrical conductivity. The substrate 10 may be made of, for example, Si, SiC, or ZnO.

The n-type layer 11 is formed on the substrate 10. The n-type layer 11 is made of Si-doped n⁻-GaN. The n-type layer 11 has a thickness of 8 μm to 15 μm. The n-type layer 11 has a Si concentration of 1×10¹⁵/cm³ to 5×10¹⁶/cm³.

The p-type region 12 is formed on a part of a surface of the n-type layer 11 up to a depth shallower than the thickness of the n-type layer 11. The p-type region 12 is made of Mg-doped p-GaN. As described later, the p-type region 12 is formed by implanting Mg ions into the surface of the n-type layer 11. The p-type region 12 has a thickness of 0.5 μm to 1 μm. A region sandwiched between the surface of the n-type layer 11 and a surface of the n-type source region 13 in a surface of the p-type region 12 constitutes a channel. The p-type region 12 has a Mg concentration of 1×10¹⁸/cm³ to 1×10¹⁹/cm³.

The n-type source region 13 is formed inside the p-type region 12 up to a depth shallower than the thickness of the p-type region 12, in a plan view. The n-type source region 13 is made of Si-doped n⁺-GaN. As described later, the n-type source region 13 is formed by implanting Si ions into the surface of the p-type region 12. The n-type source region 13 has a thickness of 0.1 μm to 0.5 μm. The n-type source region 13 has a Si concentration of 1×10¹⁸/cm³ to 1×10¹⁹/cm³.

The gate insulating film 14 is continuously disposed over the surface of the n-type layer 11, the surface of the p-type region 12, and the surface of the n-type source region 13. The gate insulating film 14 is made of, for example, SiO₂, SiN, SiON, and the like.

The source electrode 15 is disposed continuously over the surface of the p-type region 12 and the surface of the n-type source region 13. The source electrode 15 is made of, for example, Ti/Al/Ti, V/Al/Ti, and Pd/Al/Ti. V/Al/Ti means a structure in which a V layer, an Al layer, and a Ti layer are deposited in this order. Hereinafter, the same shall apply in this specification.

The drain electrode 16 is formed entirely on a back surface of the substrate 10. The drain electrode 16 is made of, for example, Ti/Al/Ti, V/Al/Ti, and Pd/Al/Ti.

The gate electrode 17 is formed on the gate insulating film 14. The gate electrode 17 has a structure in which a first barrier layer 17A, a metal layer 17B, and a second barrier layer 17C are deposited in this order on the gate insulating film 14.

The first barrier layer 17A prevents the metal of the metal layer 17B from diffusing into the gate insulating film 14. The first barrier layer 17A is made of TiN. The first barrier layer 17A may also be made of Ta, TaN, Mo, or W other than TiN. The first barrier layer 17A has a thickness of, for example, 50 nm to 300 nm.

The metal layer 17B ensures the conductivity of the gate electrode 17. The metal layer 17B is made of Al. The metal layer 17B may be made of an alloy mainly composed of Al. The alloy mainly composed of Al includes, for example, AlSi, AlCu, and the like. The metal layer 17B has a thickness of, for example, 50 nm to 400 nm.

The second barrier layer 17C protects the metal layer 17B. The second barrier layer 17C is made of TiN. The second barrier layer 17C may also be made of Ta, TaN, Mo, or W other than TiN. The second barrier layer 17C may be made of a material different from the material of the first barrier layer 17A. The second barrier layer 17C has a thickness of, for example, 20 nm to 100 nm.

A side surface 17Ba of the metal layer 17B is disposed inside a side surface 17Aa of the first barrier layer 17A and inside a side surface 17Ca of the second barrier layer 17C. In the first embodiment, the side surface 17Aa of the first barrier layer 17A is flushed with the side surface 17Ca of the second barrier layer 17C, but they may not be flushed.

Thus, the side surface 17Ba of the metal layer 17B is recessed more inward than the side surface 17Aa of the first barrier layer 17A and the side surface 17Ca of the second barrier layer 17C. Therefore, a distance from the side surface 17Ba of the metal layer 17B to the gate insulating film 14 through the surface protective film 18 is increased. In addition, Al is trapped in the recess, making it difficult for Al to diffuse from the recess. As a result, less Al reaches the gate insulating film 14 after being diffused from the side surface 17Ba of the metal layer 17B. Thus, the diffusion of Al from the side surface 17Ba of the metal layer 17B to the gate insulating film 14 can be suppressed.

Preferably, the side surface 17Ba of the metal layer 17B is disposed 10 nm to 500 nm inward from the side surface 17Aa of the first barrier layer 17A and the side surface 17Ca of the second barrier layer 17C. The diffusion of Al from the side surface 17Ba of the metal layer 17B to the gate insulating film 14 can be more suppressed.

The side surfaces 17Aa, 17Ba, and 17Ca may be formed perpendicular to or inclined with respect to the main surface of the substrate 10. Preferably, the side surfaces 17Aa, 17Ba, and 17Ca are formed inclined in a range of 65° to 85° with respect to the main surface of the substrate 10.

The gate insulating film 14 and the first barrier layer 17A, the first barrier layer 17A and the metal layer 17B, and the metal layer 17B and the second barrier layer 17C need not be in contact, and a layer made of metal may be interposed between them. A layer made of metal may be additionally disposed on the second barrier layer 17C.

The surface protective film 18 is disposed to cover an entire top surface of the semiconductor element 1. The surface protective layer 18 is in contact with the surface and side surface of the gate electrode 17, the surface of the gate insulating film 14, the surface of the n-type source region 13, and the surface of the source electrode 15. However, a hole passing through the surface protective film 18 is formed at positions corresponding to a part of the surface of the source electrode 15 and a part of the surface of the gate electrode 17 in the surface protective film 18. Through these holes, the source electrode 15 and the gate electrode 17 are connected to the outside. The surface protective film 18 may be made of SiO₂, SiN, SiON, or the like, and may have a layered structure made of a plurality of types of materials.

In the side surface of the gate electrode 17, a recess is formed in a vicinity of the side surface 17Ba of the metal layer 17B, and the surface protective film 18 is formed to fill the recess. The side surface 17Ba of the metal layer 17B and the surface protective film 18 are in contact with each other. By forming the side surface 17Ba of the metal layer 17B to be in contact with the surface protective film 18, the operation of the semiconductor element 1 can be stabilized.

In the semiconductor element 1 according to the first embodiment, the side surface 17Ba of the metal layer 17B of the gate electrode 17 is disposed inside the side surface 17Aa of the first barrier layer 17A and the side surface 17Ca of the second barrier layer 17C. Therefore, Al in the metal layer 17B can be suppressed from diffusing into the gate insulating film 14.

### 2. Method for Manufacturing Semiconductor Element

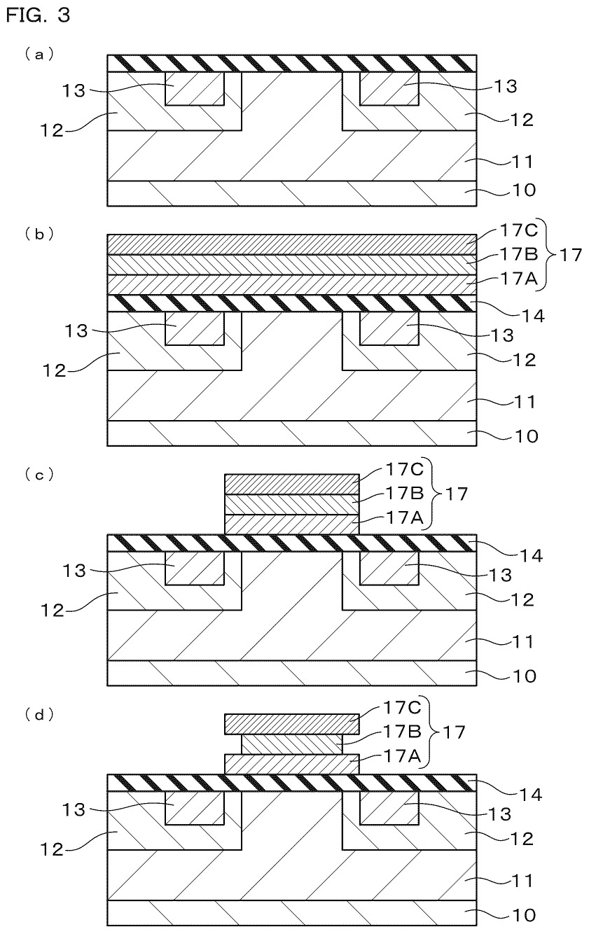

Next will be described the steps of manufacturing the semiconductor element 1 according to the first embodiment with reference to FIGS. 2 and 3.

Firstly, prepare a substrate 10, clean the surface of the substrate 10, and then form an n-type layer 11 on the substrate 10 through Metal Organic Chemical Vapor Deposition (MOCVD) (see FIG. 2(a)).

Subsequently, Mg ions are implanted up to a predetermined depth in a predetermined region on the surface of the n-type layer 11 to form a p-type region 12 (see FIG. 2(b)). Although the Mg ion implanted region obtains p-type conductivity after heat treatment in a subsequent step, for simplicity of explanation, it is referred to as the p-type region 12 even before it obtains p-type conductivity.

Si ions are implanted up to a predetermined depth in a predetermined region on the surface of the p-type region 12 to form an n-type source region 13 (see FIG. 2(c)). The Si ion implanted region obtains n-type conductivity after heat treatment in a subsequent step, but for simplicity of explanation, it is referred to as the n-type source region 13 even before it obtains n-type conductivity.

Next, heat treatment is performed under an inert gas atmosphere, such as nitrogen gas, which causes the p-type region 12 to have p-type conductivity and the n-type source region 13 to have n-type conductivity.

In the first embodiment, the p-type region 12 and n-type source region 13 are formed by ion implantation, but they may be formed by MOCVD regrowth. In other words, after the n-type layer 11 is formed, a predetermined region of the n-type layer 11 may be etched to form a recess, and the p-type region 12 may be formed by epitaxial growth to fill the recess. A predetermined region of the p-type region 12 may be etched to form a recess, and the n-type source region 13 may be formed by epitaxial growth to fill the recess. Epitaxial growth of the p-type region 12 and the n-type source region 13 is superior in terms of dimensional controllability and impurity concentration controllability.

Next, a gate insulating film 14 is continuously formed on the n-type layer 11, the p-type region 12, and the n-type source region 13 (see FIG. 3(a)).

Subsequently, a gate electrode 17 is formed on the gate insulating film 14 by forming a first barrier layer 17A, a metal layer 17B, and a second barrier layer 17C in this order through vapor deposition or sputtering (see FIG. 3(b)).

A part of the gate electrode 17 is etched in a vertical direction (perpendicular to a main surface of the substrate 10 or the n-type layer 11) by dry etching to form the gate electrode 17 in a predetermined pattern (see FIG. 3(c)). Chlorine gas is used as etching gas, for example, a mixture gas of BCl₃ and Cl₂. The etching pressure is, for example, 0.6 Pa or less.

The side surface 17Ba of the metal layer 17B of the gate electrode 17 is etched in a lateral direction (horizontal to a main surface of the substrate 10 or the n-type layer 11) by dry etching (see FIG. 3(d)). Chlorine gas is used as etching gas, for example, a mixture gas of BCl₃ and Cl₂, the same gas used in the previous step. The etching pressure in this step is set to be higher than that in the previous step, for example, 1 Pa to 5 Pa. By increasing the etching pressure in this way, the molecular weight per unit volume is increased, and scattering of the etching gas easily occurs. As a result, lateral etching can be promoted.

Here, the etching rate for the side surface 17Aa of the first barrier layer 17A and the side surface 17Ca of the second barrier layer 17C is sufficiently lower than the side surface 17Ba of the metal layer 17B. This is because Al in the metal layer 17B is easier to be etched than TiN in the first barrier layer 17A and second barrier layer 17C. As a result, the side surface 17Ba of the metal layer 17B is more inward than the side surface 17Aa of the first barrier layer 17A and the side surface 17Ca of the second barrier layer 17C. Thus, a recess is formed inward at the position of the side surface 17Ba of the metal layer 17B.

In the first embodiment, the etching rate is varied by changing the etching pressure to promote lateral etching, but the etching rate may be changed by biasing the substrate 10.

Next, a gate insulating film 14 is formed in a predetermined pattern by dry etching. Then, a source electrode 15 is formed in a predetermined region on the surface of the p-type region 12 and the surface of the n-type source region 13 through vapor deposition or sputtering, and a drain electrode 16 is formed on a back surface of substrate 10 through vapor deposition or sputtering. Furthermore, a surface protective film 18 is formed to cover an entire top surface of the semiconductor element 1. Thus, the semiconductor element 1 according to the first embodiment is manufactured.

The surface protective film 18 may be formed by Atomic Layer Deposition (ALD). Since ALD has excellent coverage, the surface protective film 18 can be formed by filling the recesses near the side surface 17Ba of the metal layer 17B. As a result, the side surface 17Ba of the metal layer 17B can be in contact with the surface protective film 18, and the operation of the semiconductor element 1 can be stabilized.

### Second Embodiment

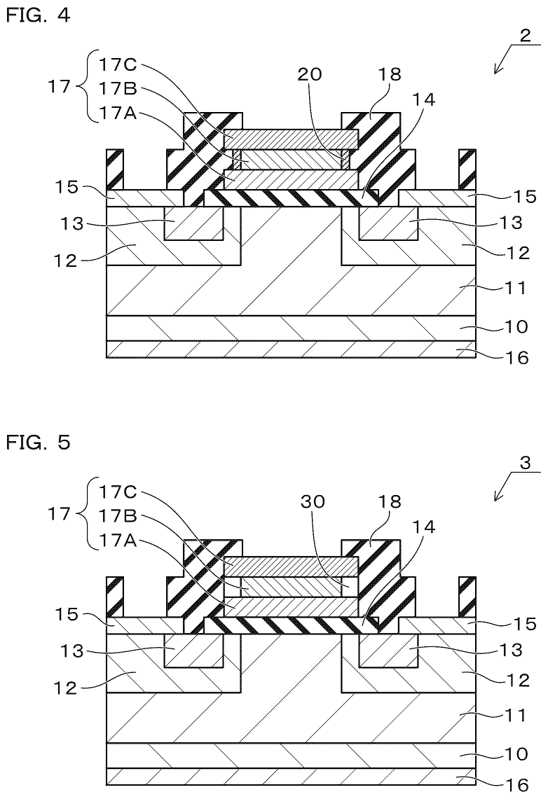

FIG. 4 is a cross-sectional view of a semiconductor element 2 according to a second embodiment, in a direction perpendicular to a main surface of a substrate 10. As shown in FIG. 2, the semiconductor element 2 according to the second embodiment is the same as the semiconductor element 1 according to the first embodiment except for that an oxide film 20 is formed between the side surface 17Ba of the metal layer 17B and the surface protective film 18.

The oxide film 20 is formed by oxidizing the side surface of the metal layer 17B of the gate electrode 17, and is made of aluminum oxide. The oxide film 20 has a thickness of 1 nm to 50 nm. The thickness of the oxide film 20 is not more than the depth of the recess in the side surface of the gate electrode 17 (a distance from the side surface 17Ba of the metal layer 17B to the side surface 17Aa of the first barrier layer 17A or the side surface 17Ca of the second barrier layer 17C). By forming the oxide film 20 made of aluminum oxide on the side surface of the metal layer 17B in this manner, the diffusion of Al from the metal layer 17B through the surface protective film 18 to the gate insulating film 14 can be further suppressed. In the second embodiment, the oxide film 20 is in contact with the surface protective film 18, but a void may exist between the oxide film 20 and the surface protective film 18 as in the third embodiment described later.

The oxide film 20 is formed by adding the step of oxidizing after laterally etching the side surface 17Ba of the metal layer 17B and before patterning the gate insulating film 14. The oxidizing step is performed by oxygen plasma treatment in an oxygen atmosphere. The oxygen plasma treatment is performed, for example, at 150 W for 20 minutes. Through the oxidizing step, the side surface 17Ba of the metal layer 17B is oxidized to form an oxide film 20 made of aluminum oxide.

### Third Embodiment

FIG. 5 is a cross-sectional view of a semiconductor element 3 according to a third embodiment, in a direction perpendicular to a main surface of a substrate 10. As shown in FIG. 5, the semiconductor element 3 according to the third embodiment is the same as the semiconductor element 1 according to the first embodiment except for that a void 30 is formed between the side surface 17Ba of the metal layer 17B and the surface protective film 18.

In the first embodiment, the side surface of the metal layer 17B was in contact with the surface protective film 18, but in the third embodiment, the side surface of the metal layer 17B is not in contact with the surface protective film 18, and the void 30 exists. The void 30 is filled with an ambient gas during the formation of the surface protective film 18.

Since there is the void 30 between the side surface of the metal layer 17B and the surface protective film 18, the diffusion of Al from the metal layer 17B through the surface protective film 18 to the gate insulating film 14, does not occur. Therefore, the diffusion of Al from the metal layer 17B to the gate insulating film 14 can be more suppressed.

The void 30 can be formed when the surface protective film 18 is formed through sputtering. Since film formation is accelerated in a direction perpendicular to the main surface of the substrate 10, the surface protective film 18 is not formed in the recess in a vicinity of the side surface 17Ba of the metal layer 17B, and the recess is left behind as the void 30.

### Fourth Embodiment

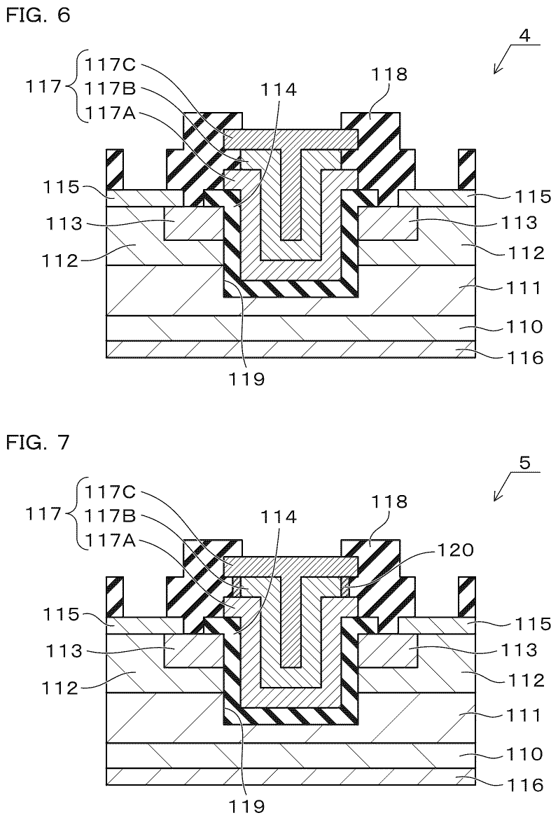

FIG. 6 is a cross-sectional view of a semiconductor element 4 according to a fourth embodiment, in a direction perpendicular to a main surface of a substrate 110. As shown in FIG. 6, the semiconductor element 4 according to the fourth embodiment constitutes a MISFET with a vertical trench gate structure. The semiconductor element 4 includes a substrate 110, an n-type layer 111, a p-type layer 112, an n-type source region 113, a gate insulating film 114, a source electrode 115, a drain electrode 116, a gate electrode 117, and a surface protective film 118.

The substrate 110 is the same as the substrate 10 in the first embodiment.

The n-type layer 111 is formed on the substrate 110. The n-type layer 111 is made of Si-doped n⁻-GaN. The n-type layer 111 has a thickness of 8 μm to 15 μm. The n-type layer 111 has a Si concentration of 1×10¹⁵/cm³ to 5×10¹⁶/cm³.

The p-type layer 112 is formed on the n-type layer 111. The p-type layer 112 is made of Mg-doped p-GaN. The p-type layer 112 has a thickness of 0.5 μm to 1 μm. The p-type layer 112 has a Mg concentration of 1×10¹⁸/cm³ to 1×10¹⁹/cm³.

The n-type source region 113 is formed on a part of a surface of the p-type layer 112 so as to have a depth shallower than the thickness of the p-type layer 112. The n-type source region 113 is made of Si-doped n⁺-GaN. The n-type source region 113 is formed by implanting Si ions into the surface of the p-type layer 112. The n-type source region 113 has a thickness of 0.1 μm to 0.5 μm. The n-type source region 113 has a Si concentration of 1×10¹⁸/cm³ to 1×10¹⁹/cm³.

A trench 119 with a depth reaching the n-type layer 111 is formed on a part of a surface of the n-type source region 113. A side surface of the p-type layer 112 exposed on a side surface of the trench 119 acts as a channel.

The gate insulating film 114 is formed in a continuous film over a bottom surface, a side surface, and a top surface of the trench 119 (in a vicinity of the trench 119 on the surface of the n-type source region 113). The material of the gate insulating film 114 is the same as the gate insulating film 14 in the first embodiment.

The source electrode 115 is disposed continuously over the surface of the p-type layer 112 and the surface of the n-type source region 113. The source electrode 115 is made of, for example, Ti/Al/Ti, V/Al/Ti, or Pd/Al/Ti.

The drain electrode 116 is formed entirely on the back surface of the substrate 110. The drain electrode 116 is made of, for example, Ti/Al/Ti, V/Al/Ti, or Pd/Al/Ti.

The gate electrode 117 is disposed continuously over the bottom surface, the side surface, and the top surface of the trench 119 through the gate insulating film 114. The gate electrode 117 has a structure in which a first barrier layer 117A, a metal layer 117B, and a second barrier layer 117C are deposited in this order on the gate insulating film 114.

The materials of the first barrier layer 117A, the metal layer 117B, and the second barrier layer 117C are the same as the materials of the first barrier layer 17A, the metal layer 17B, and the second barrier layer 17C, respectively, in the first embodiment.

The side surface of metal layer 117B is also disposed inside the side surface of the first barrier layer 117A and the side surface of the second barrier layer 117C, as is the side surface of the metal layer 17B in the first embodiment.

The surface protective film 118 is disposed to cover an entire top surface of the semiconductor element 4 and to fill a recess in a vicinity of the side surface of the metal layer 117B. Therefore, the side surface of the metal layer 117B is in contact with the surface protective film 118.

As described above, in the semiconductor element 4 according to the fourth embodiment similarly as in the semiconductor element 1 according to the first embodiment, the side surface of the metal layer 117B of the gate electrode 117 is disposed inside the side surface of the first barrier layer 117A and the side surface of the second barrier layer 117C. Therefore, the diffusion of Al from the metal layer 117B to the gate insulating film 114 can be suppressed.

Since the semiconductor element 4 according to the fourth embodiment has a trench gate structure, the etching rate when etching the side surface of the metal layer 117B in a lateral direction can be higher than that in the first embodiment. Thus, the etching time can be shortened. Although the gate insulating film 114 is also etched in this etching, the etching amount of the gate insulating film 114 can be reduced by shortening the etching time, and the reliability of the semiconductor element 4 can be improved. Moreover, the etching pressure can be lower than that in the first embodiment, for example, 0.6 Pa to 3 Pa. By keeping the etching pressure low, scattering of the etching gas can be suppressed, and controllability and reproducibility of etching shape can be improved.

The reason for faster lateral etching of the side surface of the metal layer 117B in the trench gate structure is assumed as follows. During dry etching, cations ionized by plasma are implanted into the metal layer, and the metal layer 117B is positively charged. In a plan view as viewed from the top of the trench, cations are distributed on the side surface of the trench in a higher density than in other regions. Here, etching is caused by the reaction of chlorine ions with the metal layer 117B. Therefore, chlorine ions as anions are attracted to the metal layer in a vicinity of the side surface of the trench with a high positive charge density. As a result, lateral etching of the side surface of the metal layer 117B is promoted.

### First Variation of Fourth Embodiment

FIG. 7 is a cross-sectional view of a semiconductor element 5 according to a first variation of the fourth embodiment, in a direction perpendicular to the main surface of the substrate 110. In the semiconductor element 5 according to the first variation of the fourth embodiment, an oxide film 120 is disposed on the side surface of the metal layer 117B as in the second embodiment in the semiconductor element 4 according to the fourth embodiment. By forming the oxide film 120, the diffusion of Al from the metal layer 117B to the gate insulating film 114 can be more suppressed.

### Second Variation of Fourth Embodiment

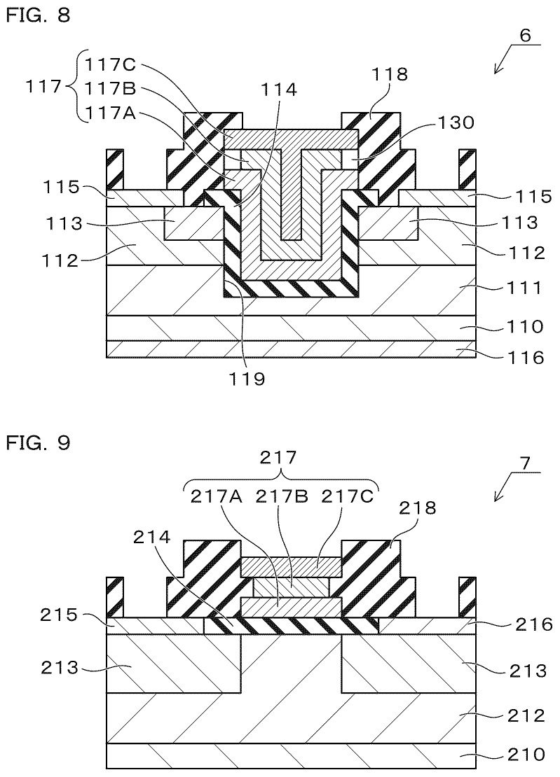

FIG. 8 is a cross-sectional view of a semiconductor element 6 according to a second variation of the fourth embodiment, in a direction perpendicular to a main surface of a substrate 110. In the semiconductor element 6 according to the second variation of the fourth embodiment, a void 130 is formed between the metal layer 117B and the surface protective film 118 in the semiconductor element 4 according to the fourth embodiment, as in the third embodiment. By forming the void 130, the diffusion of Al from the metal layer 117B to the gate insulating film 114 can be more suppressed.

### Fifth Embodiment

FIG. 9 is a cross-sectional view of a semiconductor element 7 according to a fifth embodiment, in a direction perpendicular to a main surface of a substrate 210. As shown in FIG. 9, the semiconductor element 7 according to the fifth embodiment constitutes a horizontal MISFET. The semiconductor element 7 includes a substrate 210, a p-type layer 212, an n-type source region 213, a gate insulating film 214, a source electrode 215, a drain electrode 216, and a gate electrode 217.

The substrate 210 is made of sapphire. Si, GaN, ScAlMgO₄ (SAM) or the like can be used other than sapphire.

The p-type layer 212 is formed on the substrate 210. The p-type layer 212 is made of Mg-doped p-GaN. The p-type layer 212 has a thickness of 0.5 μm to 1 μm. A surface of the p-type layer 212 sandwiched between the surfaces of two n-type source regions 213 constitutes a channel. The p-type layer 212 has a Mg concentration of 1×10¹⁸/cm³ to 1×10¹⁹/cm³.

The n-type source region 213 is disposed at two positions a distance apart on a part of the surface of the p-type layer 212, and is formed so as to have a depth shallower than the thickness of the p-type layer 212. The n-type source region 213 is made of Si-doped n⁺-GaN. The n-type source region 213 is formed by implanting Si ions into the surface of the p-type layer 212. The n-type source region 213 has a thickness of 0.1 μm to 0.5 μm. The n-type source region 213 has a Si concentration of 1×10¹⁸/cm³ to 1×10¹⁹/cm³.

The gate insulating film 214 is formed in a continuous film over a surface of one of the two separated n-type source regions 213, a surface of the p-type layer 212 sandwiched between the two n-type source regions 213, and a surface of the other of the two separated n-type source regions 213. The material of the gate insulating film 214 is the same as the material of the gate insulating film 14 in the first embodiment.

The source electrode 215 is formed on the surface of one of the two separated n-type source regions 213. The material of the source electrode 215 is the same as the source electrode 15 in the first embodiment.

The drain electrode 216 is formed on the surface of the other of the two separated n-type source regions 213 (the one not formed with the source electrode 215). The material of the drain electrode 216 is the same as the material of the drain electrode 16 in the first embodiment.

The gate electrode 217 is formed on the gate insulating film 214. The gate electrode 217 has a structure in which a first barrier layer 217A, a metal layer 217B, and a second barrier layer 217C are deposited in this order on the gate insulating film 214.

The materials of the first barrier layer 217A, the metal layer 217B, and the second barrier layer 217C are the same as the materials of the first barrier layer 17A, the metal layer 17B, and the second barrier layer 17C, respectively, in the first embodiment.

A side surface of the metal layer 217B is also disposed inside the side surface of the first barrier layer 217A and the side surface of the second barrier layer 217C, as is the side surface of the metal layer 17B in the first embodiment.

The surface protective film 218 is formed to cover an entire top surface of the semiconductor element 7 and to fill the recess in a vicinity of the side surface of the metal layer 217B. Therefore, the side surface of the metal layer 217B is in contact with the surface protective film 218.

In the semiconductor element 7 according to the fifth embodiment, the side surface of the metal layer 217B is disposed inside the side surface of the first barrier layer 217A and the side surface of the second barrier layer 217C, as in the semiconductor element 1 according to the first embodiment. Therefore, the diffusion of Al from the metal layer 217B to the gate insulating film 214 can be suppressed.

In the semiconductor element 7 according to the fifth embodiment, an oxide film may be formed on the side surface of the metal layer 217B as in the second embodiment, or a void may be formed between the side surface of the metal layer 217B and the surface protective film 218, as in the third embodiment.

### First Variation of First to Fifth Embodiments

In the first to fifth embodiments, the gate electrode was etched in the direction perpendicular to the main surface of the substrate to form a predetermined pattern, and then the side surface of the metal layer was etched. However, these may be done simultaneously. This is possible by controlling the lateral etching rate to be sufficiently fast.

The lateral etching rate can be controlled by the etching pressure. For example, by using a mixture gas of BCl₃ and Cl₂ as the etching gas at an etching pressure of 1 Pa to 5 Pa, etching in the direction perpendicular to the main surface of the substrate 10 of the gate electrode 17 and etching the side surface of the metal layer 17B can be performed simultaneously.

Such a method does not require varying the etching pressure and simplifies the manufacturing steps, thereby improving productivity.

### Second Variation of First to Fifth Embodiments

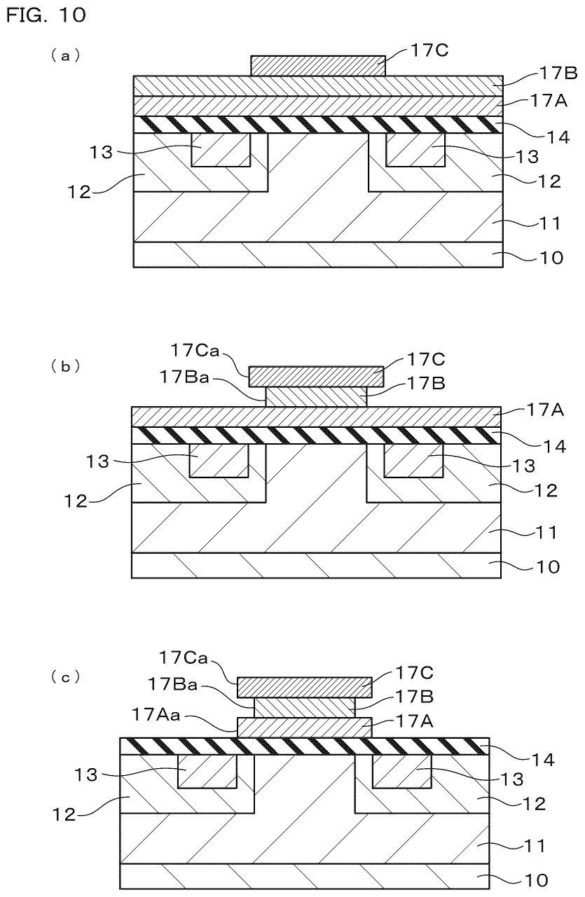

In the semiconductor element according to the first to fifth embodiments, the steps of manufacturing the gate electrode may be as shown in FIG. 10. In FIG. 10, the steps of manufacturing the gate electrode of the semiconductor element 1 according to the first embodiment is shown as an example, but the same is applicable to other embodiments as well.

In the same manner as shown in FIG. 3(b), the gate electrode 17 is formed by depositing the first barrier layer 17A, metal layer 17B, and second barrier layer 17C in this order on the gate insulating film 14.

Next, the second barrier layer 17C is etched until the metal layer 17B is exposed by dry etching (see FIG. 10(a)).

Subsequently, the metal layer 17B is etched vertically by dry etching until the first barrier layer 17A is exposed, and then the side surface 17Ba of the metal layer 17B is etched laterally by dry etching (see FIG. 10(b)). Thus, the side surface 17Ba of the metal layer 17B is disposed inside the side surface 17Ca of the second barrier layer 17C. As shown in the first variation of the first to fifth embodiments, the vertical etching of the metal layer 17B and the lateral etching of the side surface 17Ba of the metal layer 17B may be performed simultaneously.

Next, the first barrier layer 17A is etched vertically by dry etching until the gate insulating film 14 is exposed so that the side surface 17Aa of the first barrier layer 17A is disposed outside the side surface 17Ba of the metal layer 17B (see FIG. 10(c)).

If each layer constituting the gate electrode 17 is dry etched individually, the accuracy of the dimensions and shape of each layer can be improved. The etching amount of the gate insulating film 14 can also be reduced, and the operational stability of the semiconductor element can be further improved.

### (Other Variations)

Although the semiconductor element according to any one of the first to fifth embodiments constitute a MISFET, the present disclosure can be applied to any semiconductor element with a structure in which an electrode is disposed via an insulating film on a semiconductor layer, and can also be applied to an electrode other than a gate electrode. For example, it can be applied to Schottky Barrier Diode (SBD), Insulated Gate Bipolar Transistor (IGBT), Heterostructure Field Effect Transistor (HFET), and others. As shown in the first to fifth embodiments, the present disclosure can be applied to both vertical and horizontal type MISFETs, and can also be applied to a trench gate type MISFET.

In the first to fifth embodiments, group III nitride semiconductor is used as a semiconductor material. However, the present disclosure can be applied to other semiconductor materials. For example, the present disclosure can be applied to group III-V semiconductor such as GaAs, AlGaAs, AlGaP, or gallium oxide semiconductor.

What is claimed is:

1. A semiconductor element comprising:
a semiconductor layer;
an insulating film disposed on the semiconductor layer;
an electrode disposed on the insulating film; and
a surface protective film covering the semiconductor layer, the insulating film, and the electrode,
wherein the electrode includes:
a first barrier layer to prevent Al from diffusing into the insulating film;
a metal layer formed on the first barrier layer and made of Al or an alloy mainly composed of Al; and
a second barrier layer formed on the metal layer to protect the metal layer, and
wherein a side surface of the metal layer is disposed inside a side surface of the first barrier layer and inside a side surface of the second barrier layer.

2. The semiconductor element according to claim 1, wherein the side surface of the metal layer is covered with an oxide film made of aluminum oxide.

3. The semiconductor element according to claim 1, wherein a void is formed between the side surface of the metal layer and the surface protective film.

4. The semiconductor element according to claim 1, wherein:
the semiconductor element has an insulating gate structure;
the insulating film includes a gate insulating film; and
the electrode includes a gate electrode.

5. The semiconductor element according to claim 1, wherein:
the semiconductor layer includes a trench;
the insulating film includes a gate insulating film continuously disposed over a bottom surface of the trench, a side surface of the trench, and a vicinity of the trench of a surface of the semiconductor layer; and
the electrode includes a gate electrode continuously disposed over the bottom surface of the trench, the side surface of the trench, and the vicinity of the trench of the surface of the semiconductor layer through the insulating film.

6. A method for manufacturing a semiconductor element comprising:
forming an insulating film on a semiconductor layer;
forming an electrode by depositing a first barrier layer to prevent Al from diffusing into the insulating film, a metal layer made of Al or an alloy mainly composed of Al, and a second barrier layer to protect the metal layer in this order on the insulating film;
etching including dry etching the electrode in a direction perpendicular to a main surface of the semiconductor layer to form a predetermined pattern, and dry etching a side surface of the metal layer so that the side surface of the metal layer is disposed inside a side surface of the first barrier layer and inside a side surface of the second barrier layer; and
forming a surface protective film to cover the semiconductor layer and the electrode.

7. The method for manufacturing the semiconductor element according to claim 6, further comprising forming a trench in the semiconductor layer before the forming the insulating film, wherein
the insulating film is formed in a continuous film over a bottom surface of the trench, a side surface of the trench, and a vicinity of the trench of the surface of the semiconductor layer, and
the electrode is formed continuously over the bottom surface of the trench, the side surface of the trench, and the vicinity of the trench of the surface of the semiconductor layer through the insulating film.

8. The method for manufacturing the semiconductor element according to claim 6, wherein the etching includes:
vertical dry etching the electrode in the direction perpendicular to the main surface of the semiconductor layer to form the predetermined pattern; and
lateral dry etching the side surface of the metal layer at an etching pressure higher than that of the vertical dry etching after the vertical dry etching.

9. The method for manufacturing the semiconductor element according to claim 6, wherein in the etching, dry etching the electrode in the direction perpendicular to the main surface of the semiconductor layer and dry etching the side surface of the metal layer are simultaneously performed.

10. The method for manufacturing the semiconductor element according to claim 6, wherein the etching includes:
dry etching the second barrier layer in the direction perpendicular to the main surface of the semiconductor layer until the metal layer is exposed to form a predetermined pattern;
etching the metal layer of dry etching the metal layer in the direction perpendicular to the main surface of the semiconductor layer until the first barrier layer is exposed, and dry etching the side surface of the metal layer, after the dry etching the second barrier layer; and
dry etching the first barrier layer in the direction perpendicular to the main surface of the semiconductor layer until the insulating film is exposed after the etching the metal layer.

11. The method for manufacturing the semiconductor element according to claim 6, further comprising oxidizing the side surface of the metal layer to form an oxide film after the etching and before the forming the surface protective film.

12. The method for manufacturing the semiconductor element according to claim 6, wherein the surface protective film is formed so that a void remains between the side surface of the metal layer and the surface protective film.
